(19) United States
(12) Patent Application Publication
(10) Pub. No.: US 2008/0283858 A1
(43) Pub. Date: Nov. 20, 2008

(54) LIGHT-EMITTING DIODE AND METHOD FOR MANUFACTURING SAME

(75) Inventors: WEN-JANG JIANG, Chu-Nan (TW); YUAN-FA CHU, Chu-Nan (TW)

Correspondence Address: PCE INDUSTRY, INC.;ATT. CHENG-JU CHIANG, 458 E. LAMBERT ROAD, FULLERTON, CA, 92835, US

(73) Assignee: FOXSEMICON INTEGRATED TECHNOLOGY, INC., Chu-Nan (TW)

(21) Appl. No.: 11/952,955

(22) Filed: Dec. 7, 2007

(30) Foreign Application Priority Data
May 18, 2007 (CN) 200710074375.2

(51) Int. Cl. H01L 33/00

(52) U.S. Cl. 257/98; 438/22; 257/E33.064

(57) ABSTRACT

A light-emitting diode includes: a light-emitting structure, a transparent electrically conductive thick film, a first electrical contact and a second electrical contact. The light-emitting structure includes a first-type cladding layer, a second-type cladding layer, and an active layer sandwiched between the first-type cladding layer and the second-type cladding layer. The transparent electrically conductive thick film is formed on the first-type cladding layer. The first electrical contact is located on the transparent electrically conductive thick film. The second electrical contact is located on the second-type cladding layer. The transparent electrically conductive thick film is made from a metal-doped metal oxide.

### BACKGROUND OF THE INVENTION

1. Technical Field

The present invention generally relates to a structure of a light-emitting diode (LED) and a method of manufacturing same.

2. Description of Related Art

A general LED includes a light-emitting structure, a positive electrical contact, and a negative electrical contact. The light-emitting structure includes an n-type cladding layer, a p-type cladding layer, and an un-doped active layer sandwiched therebetween. The positive electrical contact is located on the p-type cladding layer, and the negative electrical contact is located on the n-type cladding layer. The light-emitting efficiency of the above described LED not only depends on a recombination rate of the electrons and the holes in the active layer, but also depends on the efficiency of current spreading in the p-type cladding layer. The resistance of the p-type cladding layer influences the distribution of current density through the p-type cladding layer. If some areas of the resistance of the p-type cladding layer are comparatively low, such as an area under the positive electrical contact, which would result in the current severely restricted to spread and thereby tends to concentrate under the positive electrical contact. This is often referred to as current crowding. Some different structures have been developed to solve the above problem in the related LED, such as, providing a transparent film between the p-type cladding layer and the positive electrical contact. The transparent film has characteristics of lower resistance, better conductivity and larger energy gap than the un-doped active layer. In the case where the p-type cladding layer is a p-type AlGaInP layer, the transparent film can be made of a semiconductor material, such as GaAsP, GaP, or AlGaAs, etc. However, the transparent film and p-type cladding layer is difficult to directly form ohmic contact therebetween and thus an additional secondary epitaxial growth for a p-type ohmic contact layer is necessary, which would render the manufacturing process of the LED to be complex and the manufacturing cost is relatively high.

What is needed, therefore, is a LED structure which has a simple manufacturing process and lower manufacturing cost, and a method for manufacturing same.

### SUMMARY OF THE INVENTION

A light-emitting diode, in accordance with a present embodiment, includes: a light-emitting structure, a transparent electrically conductive thick film, a first electrical contact and a second electrical contact. The light-emitting structure includes a first-type cladding layer, a second-type cladding layer, and an active layer sandwiched between the first-type cladding layer and the second-type cladding layer. The transparent electrically conductive thick film is formed on the first-type cladding layer. The first electrical contact is formed on aside of the transparent electrically conductive thick film opposite to the first-type cladding layer. The second electrical contact is formed on aside of the second-type cladding layer opposite to the active layer. The transparent electrically conductive thick film is comprised of a metal-doped metal oxide.

A method for manufacturing a light-emitting diode, in accordance with another present embodiment, includes the steps: (a) providing a substrate; (b) forming a light-emitting structure on the substrate, the light-emitting structure including a first-type cladding layer, an active layer and a second-type cladding layer, along a direction facing toward the substrate; (c) forming a transparent electrically conductive thick film on the first-type cladding layer using the metal-doped metal oxide; (d) removing the substrate from the second-type cladding layer; and (e) forming a first electrical contact and a second electrical contact, respectively, on the transparent electrically conductive thick film and the second-type cladding layer.

The transparent electrically conductive thick film of the light-emitting diode, in accordance with the present embodiments, is made from a metal-doped metal oxide. Many doped metal in the transparent electrically conductive thick film can diffuse into the first-type cladding layer, and thus a better ohmic contact would be formed between the transparent electrically conductive thick film and the first-type cladding layer.

Other advantages and novel features will become more apparent from the following detailed description of the present invention, when taken in conjunction with the accompanying drawings.

### BRIEF DESCRIPTION OF THE DRAWINGS

Many aspects of the present light-emitting diode and method for manufacturing same can be better understood with reference to the following drawings. The components in the drawings are not necessarily drawn to scale, the emphasis instead being placed upon clearly illustrating the principles of the present light-emitting diode and method for manufacturing same.

FIG. 1 is a schematic, sectional cross-sectional view of a light-emitting diode, in accordance with a first embodiment.

FIG. 2 is schematic, sectional cross-sectional view of a light-emitting diode, similar to that of FIG. 1, but showing the second electrical contact being consisted of many point-like electrodes.

FIG. 3 is a flow chart of a method for manufacturing a light-emitting diode, in accordance with a second embodiment.

FIG. 4 to FIG. 7 are schematic, sectional cross-sectional views of structures associated with respective stages of a method in FIG. 3.

Corresponding reference characters indicate corresponding parts throughout the drawings. The exemplifications set out herein illustrate at least one embodiment of the present light-emitting diode and method for manufacturing same, in one form, and such exemplifications are not to be construed as limiting the scope of the invention in any manner.

### DETAILED DESCRIPTION OF THE EMBODIMENTS

Reference will now be made to the drawings to describe the embodiments of the present light-emitting diode and method for manufacturing same.

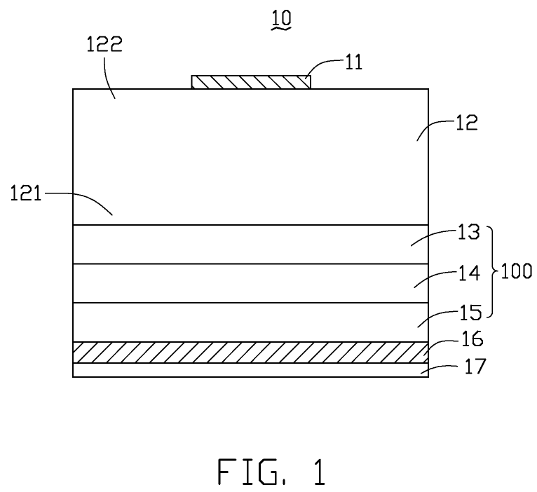

Referring to FIG. 1, a light-emitting diode with high brightness, in accordance with a first embodiment, is provided. The light-emitting diode 10 includes: a p-type electrical contact 11, a transparent electrically conductive thick film 12, a light-emitting structure 100, and an n-type electrical contact 16. The light-emitting structure 100 includes a p-type cladding layer 13, an n-type cladding layer 15 and an active layer 14 sandwiched in-between.

The transparent electrically conductive thick film 12 can be a single layer structure or a multilayer structure, and has a thickness in the range from about 200 nanometers to about 200 micrometers. In the present embodiment, the transparent electrically conductive thick film 12 is a single layer structure and has a thickness of 100 micrometers.

The transparent electrically conductive thick film 12 is light-transmissive and electrically conductive. The transparent electrically conductive thick film 12 suitably is comprised of metal-doped metal oxide. A dopant metal in the metal-doped metal oxide is selected from the group consisting of indium (In), tin (Sn), zinc (Zn), tellurium (Te), antimony (Sb), aluminum (Al) and any combination thereof. The metal-doped metal oxide can be an indium-doped tin oxide (SnO:In), tin-doped gallium oxide (Ga₂O₃:Sn), tin-doped indium silver oxide (AgInO₂:Sn), indium tin oxide (ITO), zinc-doped indium oxide (In₂O₃:Zn), antimony-doped tin dioxide (SnO₂:Sb), aluminum-doped zinc oxide (ZnO:Al), etc.

The transparent electrically conductive thick film 12 has a thickness in the range from about 200 nanometers to about 200 micrometers. The density of the dopant metal in the transparent electrically conductive thick film 12 is enough. As a result, the dopant metal can diffuse into the p-type cladding layer 13 to form a better ohmic contact between the transparent electrically conductive thick film 12 and the p-type cladding layer 13.

The transparent electrically conductive thick film 12 has a first end 121 and a second end 122. The first end 121 is located proximate to the p-type cladding layer 13. The second end 122 is located facing away from the p-type cladding layer 13. A dopant concentration of the first end 121 is higher than that of the second end 122 thereof, which also improves the ohmic contact between the transparent electrically conductive thick film 12 and the p-type cladding layer 13.

In addition, when a middle region of the transparent electrically conductive thick film 12, i.e., a region between the first end 121 and the second end 122, has a higher content of oxygen atoms, the light-absorption phenomenon caused by oxygen defects in the transparent electrically conductive thick film 12 could be effectively suppressed.

The transparent electrically conductive thick film 12 serves as a window layer of the light-emitting diode 10, the light emitted from the light-emitting structure 100 transmits through the transparent electrically conductive thick film 12. It is understood that a wavelength-conversion material, e.g., phosphor material, can be contained in the transparent electrically conductive thick film 12. The wavelength-conversion material converts the wavelength of radiation emitted from the light-emitting structure 100, into a relatively longer wavelength of radiation. For example, the light-emitting structure 100 could emit blue light, and the wavelength-conversion material, correspondingly, can be a yellow phosphor so as to enable the light-emitting diode 10 to emit white light.

The body of the p-type cladding layer 13, the active layer 14, and the n-type cladding layer 15 can be the III-V compound or the Il-VI compound. For example, the body of the p-type cladding layer 13 and the n-type cladding layer 15 are GaN, AlGaN, AlGaInP, etc., the body of the active layer 14 is InGaN, AlGaAs etc. In addition, the active layer 14 could further contain titanium (Ti), cadmium-silicon (Cd—Si), cadmium-tellurium (Cd—Te), zinc-silicon (Zn—Si), zinc-tellurium (Zn—Te) or other material configured to modify the energy gap of the active layer 14.

Furthermore, the p-type cladding layer 13 could also contain indium, tin, zinc, antimony, aluminum or any combination thereof. In the present embodiment, the indium is distributed in a region of the p-type cladding layer 13, which is proximate to the transparent electrically conductive thick film 12, thus much more indium atoms can easily bond with the dopant metal in the transparent electrically conductive thick film 12 by bonging force, which would improve ohmic contact between the transparent electrically conductive thick film 12 and the p-type cladding layer 13.

The first electrical contact 11 is formed on an opposite side of the transparent electrically conductive thick film 12 to the p-type cladding layer 13. The second electrical contact 16 is formed on an opposite side of the n-type cladding layer 15 to the active layer 14. The first electrical contact 11 and the second electrical contact 16 both include at least one of the aurum (Au), aluminum (Al), titanium-aurum (Ti—Au), chromium-aurum (Cr—Au), chromium-aluminum (Cr—Al), nickel-aurum (Ni—Au) and nickel-aluminum (Ni—Al).

The second electrical contact 16 can be a transparent conducting layer, this transparent conducting layer is comprised of metal-doped metal oxide. The dopant metal in the metal-doped metal oxide is selected from the group consisting of indium, tin, zinc, tellurium, antimony, aluminum and any combination thereof. The metal-doped metal oxide can be an Indium-doped tin oxide (SnO:In), tin-doped gallium oxide (Ga₂O₃:Sn), tin-doped indium silver oxide (AgInO₂:Sn), indium tin oxide (ITO), Zinc-doped indium oxide (In₂O₃:Zn), Antimony-doped tin dioxide (SnO₂:Sb), Aluminum-doped zinc oxide (ZnO:Al), etc.

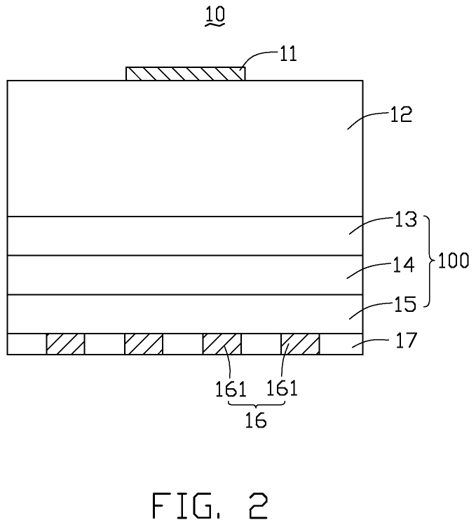

Referring to FIG. 2, the second electrical contact 16 includes many point-like electrodes 161, the point-like electrodes 161 are used to guide current entering the n-type cladding layer 15 to transverse diffusion effectively, so that the current can be distributed uniformly.

The light-emitting diode 10 further includes a metallic reflective layer 17 which is used to reflect the light incident into the second electrical contact 16, so that brightness of the light-emitting diode 10 can be improved. The metallic reflective layer 17 is deposed on the second electrical contact 16. The metallic reflective layer 17 includes metal with high reflectivity, such as aluminum, silver etc. It is understood that the metallic reflective layer 17 can be a Bragg reflector.

The first electrical contact 11 and the second electrical contact 16 are used to provide voltage to the light-emitting structure for emitting light therefrom.

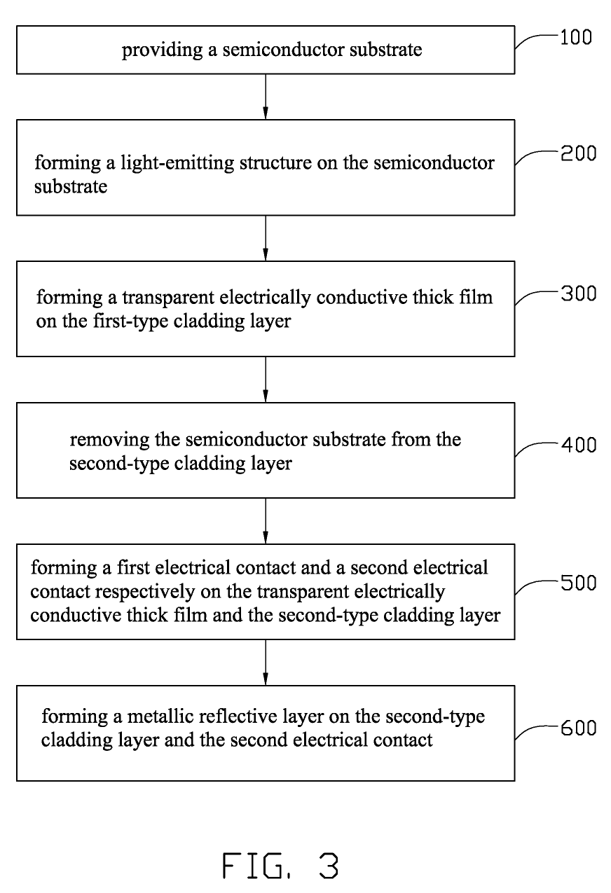

Referring to FIG. 3, a method for manufacturing a light-emitting diode, in accordance with a second embodiment, is shown. The method includes the following steps:

Step 100: providing a semiconductor substrate 31.

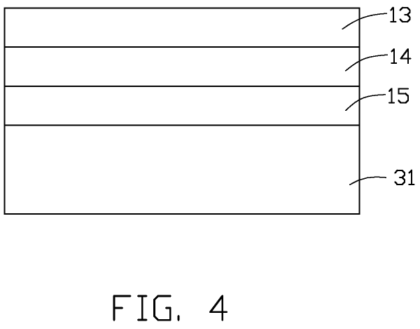

Step 200: referring to FIG. 4, forming a light-emitting structure on the semiconductor substrate 31 by means of the MOVPE process, MBE process, MOCVD process or other process. The light-emitting structure comprises the n-type cladding layer 15 formed on the substrate 31, the active layer 14 formed on the n-type cladding layer 15, the p-type cladding layer 13 is formed on the active layer 14.

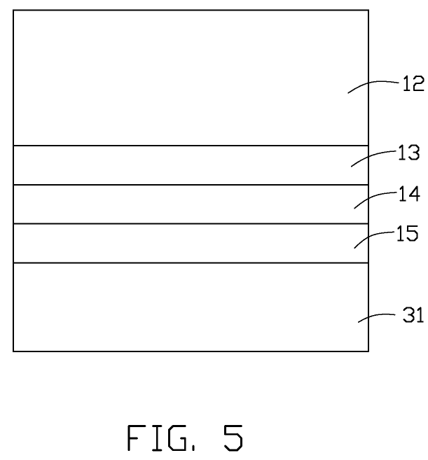

Step 300: referring to FIG. 5, forming the transparent electrically conductive thick film 12 on the first-type cladding layer by means of reactive evaporation, wafer bonding or other process, wherein the transparent electrically conductive thick film 12 is comprised of a metal-doped metal oxide. In the present embodiment, the first-type cladding layer is the p-type cladding layer 13.

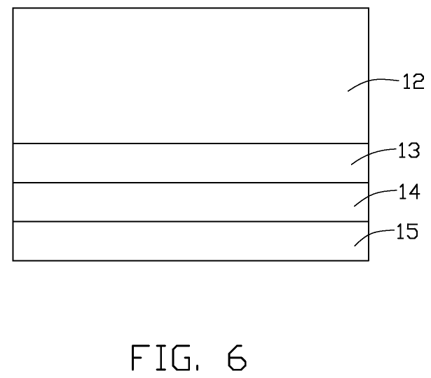

Step 400: referring to FIG. 6, removing the semiconductor substrate 31 from the second-type cladding layer by means of grinding, selective etching, laser lift-off or other process. In the present embodiment, the second-type cladding layer is the n-type cladding layer 15.

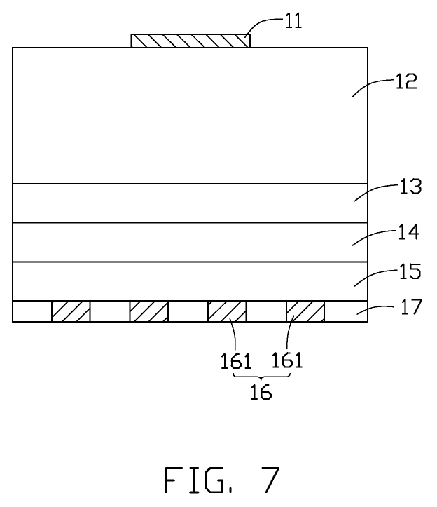

Step 500: referring to FIG. 7, forming the first electrical contact 11 and the second electrical contact 16 respectively on the transparent electrically conductive thick film 12 and the second-type cladding layer. The second electrical contact 16 is composed of a number of point-like electrodes 161.

Step 600: referring to FIG. 7, forming the metallic reflective layer 17 on the second-type cladding layer and the second electrical contact 16 by use of sputter, evaporation or ion beam sputtering processes to deposit hafnium oxide/silicon oxide (HfO₂/SiO₂), titanium oxide/silicon oxide (TiO₂/SiO₂), silicon nitride/silicon oxide (SiNₓ/SiO₂) or any combination thereof onto the second electrical contact 16 to form the metallic reflective layer 17.

Furthermore, a metallic film can be coated on the p-type cladding layer 13 after the step 200 of growing the light-emitting structure on the semiconductor substrate 31 and before the step 300 of bonding the transparent electrically conductive thick film 12 to the p-type cladding layer 13. The metallic film is selected from the group consisting of indium, tin, zinc, tellurium, antimony, aluminum and any combination thereof. In this embodiment, an indium film is fixedly bonded with the p-type cladding layer 13 by heating with a high temperature in the range of 300˜400° C. As a result of that, the indium atoms in the indium film are diffused into the p-type cladding layer 13. So as to improve ohmic contact between the transparent electrically conductive thick film 12 and the p-type cladding layer 13.

It is to be understood that the above-described embodiment is intended to illustrate rather than limit the invention. Variations may be made to the embodiment without departing from the spirit of the invention as claimed. The above-described embodiments are intended to illustrate the scope of the invention and not restrict the scope of the invention.

What is claimed is:

1. A light-emitting diode comprising:
a light-emitting structure comprising a first-type cladding layer, a second-type cladding layer and an active layer sandwiched between the first-type cladding layer and the second-type cladding layer;
a transparent electrically conductive thick film formed on the first-type cladding layer, which is comprised of a metal-doped metal oxide;
a first electrical contact formed on a side of the transparent electrically conductive thick film opposite to the first-type cladding layer; and
a second electrical contact formed on a side of the second-type cladding layer opposite to the active layer.

2. The light-emitting diode of claim 1, wherein the transparent electrically conductive thick film has a first end proximate to the first-type cladding layer and a second end facing away from the first-type cladding layer, a dopant concentration of the first end of the transparent electrically conductive thick film being higher than that of the second end thereof.

3. The light-emitting diode of claim 1, wherein the transparent electrically conductive thick film has a thickness in the range from about 200 nanometers to 200 micrometers.

4. The light-emitting diode of claim 1, wherein a middle region between the first end and the second end of the transparent electrically conductive thick film, has a higher content for oxygen atoms.

5. The light-emitting diode of claim 1, wherein a dopant metal in the metal-doped metal oxide is selected from the group consisting of indium, tin, zinc, tellurium, antimony, aluminum and any combination thereof.

6. The light-emitting diode of claim 5, wherein the metal-doped metal oxide is selected from the group consisting of indium-doped tin oxide, tin-doped gallium oxide, tin-doped indium silver oxide, indium tin oxide, zinc-doped indium oxide, antimony-doped tin dioxide and aluminum-doped zinc oxide.

7. The light-emitting diode of claim 1, wherein the transparent electrically conductive thick film contains a wavelength-conversion material.

8. The light-emitting diode of claim 1, wherein the doped metal in the first-type cladding layer is selected from the group consisting of indium, tin, zinc, antimony, aluminum and any combination thereof.

9. The light-emitting diode of claim 8, wherein the doped metal is distributed in a region of the first-type cladding layer proximate to the transparent electrically conductive thick film.

10. The light-emitting diode of claim 1, wherein the second electrical contact is a transparent conducting layer made from indium-doped tin oxide, tin-doped gallium oxide, tin-doped indium silver oxide, indium tin oxide, zinc-doped indium oxide, antimony-doped tin dioxide or aluminum-doped zinc oxide.

11. The light-emitting diode of claim 1, wherein the second electrical contact includes a plurality of point-like electrodes.

12. A method for manufacturing a light-emitting diode, comprising the steps of:
(a) providing a semiconductor substrate;
(b) forming a light-emitting structure on the semiconductor substrate, the light-emitting structure comprising a second-type cladding layer formed on the semiconductor substrate, an active layer formed on the second-type cladding layer and a first-type cladding layer formed on the active layer;
(c) forming a transparent electrically conductive thick film on the first-type cladding layer, the transparent electrically conductive thick film being comprised of a metal-doped metal oxide;
(d) removing the semiconductor substrate from the second-type cladding layer; and
(e) forming a first electrical contact and a second electrical contact respectively on the transparent electrically conductive thick film and the second-type cladding layer.

13. The method of claim 12, wherein the method further comprises a step of forming a metallic film on the second-type cladding layer after the step (b).
